(19) United States
(12) Patent Application Publication
(10) Pub. No.: US 2026/0291206 A1
(43) Pub. Date: Sep. 24, 2026

(54) Ground Fault Circuit Interrupter with Solid State Relay-Controlled Electromagnetic Contactor and Self-Test End of Life (STEOL) Circuits for High-Current Applications

(71) Applicant: Tower Manufacturing Corp., Providence, RI (US)

(72) Inventors: Gregory J. Streb, Danielson, CT (US); Daniel J Paquette, Woonsocket, RI (US); Victor V. Aromin, West Warwick, RI (US)

(21) Appl. No.: 19/686,854

(22) Filed: May 25, 2026

Related U.S. Application Data
(63) Continuation-in-part of application No. 19/339,910, filed on Sep. 25, 2025, now Pat. No. 12,695,292.
Application No. 19/339,910 is a continuation-in-part of application No. 19/063,815, filed on Feb. 26, 2025, now Pat. No. 12,451,683.
Application No. 19/063,815 is a continuation-in-part of application No. 18/760,562, filed on Jul. 1, 2024, now Pat. No. 12,292,475.

(51) Int. Cl. H02H 3/16; G01R 31/28; H01H 47/00; H02H 1/00; H02H 3/05

(52) U.S. Cl. CPC H02H 3/162; G01R 31/2827; H01H 47/007; H02H 1/0007; H02H 3/05

(57) ABSTRACT

A ground fault circuit interrupter (GFCI) with self-test end-of-life (STEOL) circuitry for 240-volt, 60-ampere applications is provided. An electromagnetic contactor with normally-open contacts on both line conductors is controlled by at least one optically-isolated solid state relay (SSR) connected in series with the contactor coil. A single sense transformer and ground fault detection integrated circuit detect current imbalances and trigger a silicon-controlled rectifier (SCR) to de-energize the SSR and open the contactor. A periodic self-test circuit exercises the fault protection circuit through a coupled winding of the sense transformer without interrupting load power. An auto-monitoring end-of-life circuit permanently denies power upon detecting failure of the fault protection circuit.

### CROSS-REFERENCE TO RELATED APPLICATIONS

The present continuation-in-part application is related to, claims the earliest available effective filing date(s) from (e.g., claims earliest available priority dates for other than provisional patent applications; claims benefits under 35 USC§ 119(e) for provisional patent applications), and incorporates by reference in its entirety all subject matter of the following listed application(s) (the “Related Applications”) to the extent such subject matter is not inconsistent herewith; the present application also claims the earliest available effective filing date(s) from, and also incorporates by reference in its entirety all subject matter of any and all parent, grandparent, great-grandparent, etc. applications of the Related Application(s) to the extent such subject matter is not inconsistent herewith:
U.S. patent application Ser. No. 19/339,910, entitled “DUAL MODE HIGH FREQUENCY GFCI/LCDI INTERRUPTER and Self-Test and End of Life (STEOL)”, naming Victor V. Aromin as first inventor, filed Sep. 25, 2025. Which is a continuation in part of:
U.S. patent application Ser. No. 19/063,815, now U.S. Pat. No. 12,451,683, entitled “High Frequency Resistant Nuisance Tripping GFCI and with Self-Test and End of Life (STEOL) Circuits”, naming Victor V. Aromin as first inventor, filed Feb. 26, 2025. Which is a continuation in part of:
U.S. patent application Ser. No. 18/760,562, now U.S. Pat. No. 12,292,475, entitled “High Frequency Resistant Nuisance Tripping GFCI and with Self-Test and End of Life (STEOL) Circuits”, naming Victor V. Aromin as first inventor, filed 1 Jul. 2024.

### 1. FIELD OF USE

The present invention relates generally to electrical safety devices and more particularly to ground fault circuit interrupters (GFCI) with self-test end-of-life (STEOL) circuitry for high-current applications. The invention specifically addresses a GFCI apparatus suitable for 240-volt, 60-ampere alternating current (AC) circuits utilizing solid state relays (SSR) controlled electromagnetic contactor switching architecture resistant to high frequency nuisance tripping.

### 2. DESCRIPTION OF PRIOR ART (BACKGROUND)

Conventional electrical appliances typically receive alternating current (AC) power from a power supply, such as an electrical outlet, through a pair of conducting lines. In high-current 240-volt applications, the pair of conducting lines comprises two line conductors, each energized with respect to ground, enabling the electrical appliance, or load, to receive the current necessary to operate.

The connection of an electrical appliance to a power supply by a pair of conducting lines creates several potentially dangerous conditions. There exists the risk of ground fault and open conductor conditions in the conducting lines. A ground fault condition occurs when there is an imbalance between the currents flowing in the two line conductors, caused by an unintended current path from either conductor to ground. An open conductor condition exists when either line conductor is open between the load and the source.

Ground fault circuit interrupters are well known in the art and are commonly used to protect against ground fault and open conductor conditions. GFCI devices sense ground fault conditions in the conducting lines and in response thereto, open at least one of the conducting lines between the power supply and the load to eliminate the dangerous condition.

A typical ground fault interrupter includes an operational amplifier which amplifies the sensed ground fault signal and applies the amplified signal to a window comparator which compares it to positive and negative reference signals. If either reference value is exceeded, a trip signal is generated. A common type of ground fault detection circuit is the dormant oscillator detector. This detector includes a first sensor coil through which the line and neutral conductors of the protected circuit pass. The output of the first sensor coil is applied through a coupling capacitor to the above-described operational amplifier followed by a window comparator. A line-to-ground fault causes the amplified signal to exceed the reference value and generates a trip signal.

Ground fault interrupters include ground fault circuit breakers, ground fault receptacles, and even cord mounted ground fault protection devices. Ground fault interrupters may be troubled by false tripping, even though they pass all present industry standards. One cause of false tripping may be disconnection of the power to inductive appliances, particularly by unplugging the appliances. It has been found that wide band noise pulses induced by load related switching phenomena can cause false tripping of typical ground fault interrupters. The wide band noise pulses typically contain frequency components ranging from greater than 60 Hz up to 150 KHz.

Another cause of false tripping of typical GFCIs may be due to the typical construction of the appliance, such as a clothes washing machine, refrigerator, or an air conditioner, constructed with variable speed drives, electronic circuits, and/or inverter drives. These devices can exhibit high frequency, e.g., greater than 60 Hz, leakage current flowing through the grounding conductor of the appliance power supply cord to the building power system.

A drawback of typical GFCI devices is that the GFCI device generally includes a large solenoid to selectively open and close the switching device. Specifically, the solenoid generally requires a constant supply of line voltage (about 120 volts) to switch and sustain the solenoid in its energized state. The solenoid acts as a large power drain source. Furthermore, conventional solenoid-latch mechanisms are designed for 120-volt, 15-ampere or 20-ampere residential applications. These mechanisms lack the contact surface area, spring pressure, and arc suppression capabilities needed to reliably interrupt and carry 60-ampere currents at 240 volts.

At 240 volts and 60 amperes, the power being switched is approximately 14,400 watts—more than seven times the power handled by a standard 120V/15 A GFCI. The contact arcing energy, the magnetic forces on current-carrying conductors, and the thermal dissipation requirements all scale dramatically. Existing approaches to high-current GFCI protection have generally employed either oversized solenoid-latch mechanisms with correspondingly large coil power requirements, or have relied on external circuit breakers triggered by a GFCI sensing circuit. The former approach results in bulky, expensive devices with high quiescent power consumption. The latter approach requires the GFCI sensing circuit and the circuit breaker to be separately specified, installed, and maintained, introducing potential points of failure.

Further, the standard UL943 requires panel mounted and receptacle based GFCIs to indicate “end of life” if the GFCI device fails to trip when the test button is manually operated. However, even if end-users regularly tested their devices, a GFCI device that did not test properly could still be reset, and continue to provide power, without providing ground-fault protection. Without a built-in power denial feature, a consumer could incorrectly assume that if power is available, so is protection.

End-of-life events test that the ground fault sensing parts (toroids and integrated circuit) are open or short circuited; the trip solenoid and/or its control circuit is faulty, or the switching semiconductor (SCR) controlling the trip solenoid control circuit is open or short circuited. Implementing these features in a high-current GFCI device without a microprocessor, using only discrete analog components, presents additional design challenges not addressed by the prior art.

Accordingly, there is a need for a GFCI capable of reliably protecting high-current 240-volt, 60-ampere AC circuits. There is a further need for a switching architecture that isolates electronic control from high-power switching functions. Additionally, there is a need for a ground fault interrupter that avoids false tripping in response to broadband noise on the protected circuit. There is also a need for a GFCI that provides both manual and automatic testing of components prone to failure, with denial of power or end-of-life switching if such testing is unsuccessful.

### SUMMARY OF THE INVENTION

It is an object of the present invention to provide a new and improved ground fault circuit interrupter (GFCI) for high-current applications.

It is another object of the present invention to provide a GFCI which senses ground fault conditions in the conducting lines, and in response thereto, includes an electromagnetic contactor controlled by solid state relays which opens the conducting lines between the power supply and the load.

The invention includes a ground fault circuit interrupter (GFCI) with end-of-life self-testing (STEOL) for interrupting the flow of current through a pair of lines is provided. One of the pair of lines extends between a first line input and a first line output and the other line extends between a second line input and a second line output. The GFCI includes a first switch SW1 having a first input terminal and a first contact terminal and a second switch SW2 having a second input terminal and a second contact terminal; the first and second switches being normally-open contacts of an electromagnetic contactor CR1. Each switch has a first non-energized (open) position and a second energized (closed) position and wherein the first switch is connected between the first line input and the first line output and the second switch is connected between the second line input and the second line output. The GFCI includes at least one solid-state relay (SSR) circuit configured to control the supply of current to the electromagnetic contactor coil, with the SSR output switches connected in series with the coil such that opening the SSR switches interrupts current to the coil and causes the first and second switches to open.

The GFCI also includes a fault detection circuit for detecting a ground fault in either line output. The fault detection circuit includes one sense transformer T1 for sensing the ground fault in either line output. To eliminate high frequency crosstalk and subsequent high frequency nuisance tripping the fault detection circuit does not comprise a second sense transformer. The fault detection circuit also includes an electronic latch circuit comprising a silicon-controlled rectifier SCR1 for de-energizing the SSR circuit when a fault is detected.

The GFCI also includes a test module integrated with the GFCI. The test module includes a simulated ground fault generator configured to periodically inject a simulated ground fault signal into the sense transformer at predetermined intervals; an auto-monitoring end-of-life logic circuit configured to monitor the cumulative response of successive self-test cycles and generate an end-of-life signal when the self-test response falls outside a predetermined operating range; and an end-of-life switch configured to permanently disable the contactor circuit upon receipt of the end-of-life signal.

Also included is a power supply circuit connected across the first and second line inputs for powering the test module, the electronic latch circuit, the fault detection circuit, and the SSR circuit. The GFCI circuit is powered by the voltage appearing across the two line inputs, and wherein an open condition on either line input removes the voltage supply from the power supply circuit, which de-energizes the contactor coil and sets the first and second switches to the first non-energized (open) position.

Sense transformer T1 is a differential current transformer. The first and second line conductors each pass through the toroidal core of T1. Under normal operating conditions the currents in the two conductors are equal and opposite, producing no net flux in the core and no output from the sense winding. A ground fault condition causes an imbalance between the two line conductor currents, producing a net flux in the core that induces a voltage in the sense winding, which is detected by the fault detection circuit.

More objects, as well as features and advantages, of the present invention will be in the description which follows, and in part will be obvious from the description or may be learned by practice of the invention. In the description, reference is made to the drawings which form a part thereof and in which is shown by way of illustration specific embodiments for practicing the invention. These embodiments will be described in enough detail to enable those skilled in the art to practice the invention, and it is to be understood that other embodiments may be used and that structural changes may be made without departing from the scope of the invention. The following detailed description is not to be taken in a limiting sense, and the scope of the present invention is best defined by the appended claims.

### BRIEF DESCRIPTION OF THE DRAWINGS

The drawings, which are incorporated into and are a part of this specification, illustrate various embodiments of the invention and, together with the description, explain the principles of the invention. In the drawings wherein like reference numerals represent like parts:

FIG. 1 is a schematic circuit diagram of a ground fault circuit interrupter (GFCI) with solid state relay-controlled electromagnetic contactor, High Frequency (HF) tripping resistance, and STEOL of the present invention; and

FIG. 2 is a timing diagram showing four synchronous voltage waveforms V(vs), V(vcap+), V(v_scr1_g), and V(vc6+) during normal STEOL self-test cycling operation over a one-second interval, where V(vs) is the GFCI supply voltage Vs, V(vcap+) is the monitored quantity of auto-monitoring end-of-life logic circuit 35, V(v_scr1_g) is the SCR1 gate voltage, and V(vc6+) is the periodic stimulus generator output voltage, demonstrating correct dynamic equilibrium behavior of the protection chain during normal operation including self-test events.

### DETAILED DESCRIPTION

### Definitions

The following brief definition of terms shall apply throughout the application:

The term “comprising” means including but not limited to, and should be interpreted in the way it is typically used in the patent context;

The term “STEOL” means “Self-Test End-Of-Life” and refers to circuitry that periodically and automatically verifies the integrity of the ground fault protection chain and permanently disables the device if that verification fails;

The phrases “in one embodiment,” “according to one embodiment,” generally mean that the particular feature, structure, or characteristic following the phrase may be included in at least one embodiment of the present invention, and may be included in more than one embodiment of the present invention (such phrases do not necessarily refer to the same embodiment);

If the specification describes something as “exemplary” or an “example,” it should be understood that refers to a non-exclusive example;

High frequency may be defined as greater than 60 Hz up to 150 KHz.

Ground fault conditions as used herein may be defined as ground fault and open conductor conditions in the two line conductors of a 240-volt, 60-ampere AC circuit. This invention employs a two-line, no-neutral topology; the concept of a grounded neutral condition as defined in single-phase 120-volt GFCI art does not apply to the circuit of the present invention.

### Overall Circuit Architecture

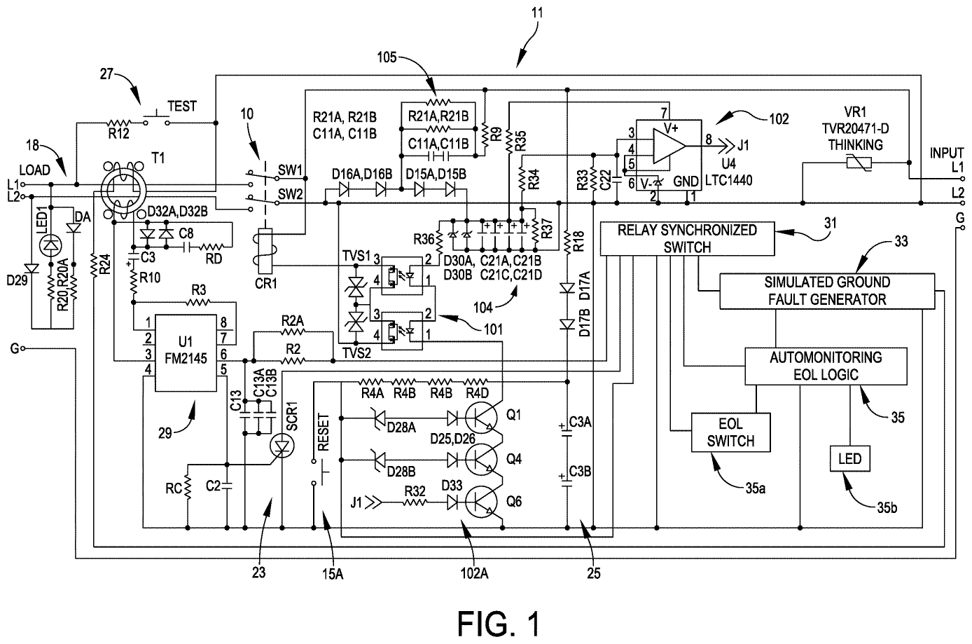

Referring now to the drawings and more particularly to FIG. 1, there is shown a ground fault circuit interrupter (GFCI) circuit constructed according to the teachings of the present invention, the GFCI being represented generally by reference numeral 11.

GFCI 11 automatically protects a load from ground fault conditions upon the initial connection of Input L1 to Load L1 and Input L2 to Load L2. GFCI 11 is designed for high-current applications at 240 volts AC, 60 amperes. Furthermore, once GFCI 11 protects the load from a ground fault condition, GFCI 11 automatically resets upon removal and restoration of the fault condition.

GFCI 11 includes an electromagnetic contactor circuit 10, a solid state relay (SSR) drive circuit 102A, a power supply circuit 105, a fault detection circuit 29, a bi-stable electronic latch circuit 23, a filter circuit 25, an indicator circuit 18. GFCI 11 also includes a test module 110. The test module 110 includes a simulated ground fault generator 33, an auto-monitoring end-of-life logic circuit 35, a relay synchronized switch circuit 31, and an end-of-life (EOL) switch 35A. EOL switch 35A also includes EOL LED 35B It will be appreciated that the circuits are powered by the first line input L1 and return through the second line conductor L2.

### Electromagnetic Contactor Circuit

Electromagnetic contactor circuit 10 includes a pair of normally-open switches SW1 and SW2 in the first and second line conductors, respectively, between a power source (input L1 and L2) and a load (load L1 and L2). Contactor circuit 10 acts to selectively open and close the pair of conductive lines. Switches SW1 and SW2 are the contacts of electromagnetic contactor CR1, which in the preferred embodiment is a type XMC0-633A-ID00F (manufactured by Hongfa) or equivalent, rated for 60-ampere contact current at 240 VAC. Each switch can be positioned in either of two positions. In the first position (de-energized), which is the normal unpowered state, switches SW1 and SW2 are open and the input power source is not connected to the load. In the second position (energized), switches SW1 and SW2 are closed and the input power source is connected to the load.

Contactor CR1 comprises a coil winding having a DC resistance of approximately 230 ohms and an inductance of approximately 9 henries. When the coil is energized with sufficient current, contactor CR1 positions switches SW1 and SW2 to the second (closed) position. When the coil is de-energized, contactor CR1 returns switches SW1 and SW2 to the first (open) position. The contacts are rated for a contact resistance of approximately 5 milliohms in the closed state.

A transient voltage suppressor (TVS) network comprising TVS1 and TVS2 arranged in a series-opposing configuration, connected across the solid state relays U2 and U3, respectively, to clamp SSR inputs/outputs when the coil is de-energized. The TVS diodes are preferably type P6SMB480CAY or P6SMB480CA or equivalent.

### Solid State Relay Circuit

Still referring to FIG. 1 SSR drive circuit 102A controls the energization and de-energization of contactor CR1 coil. SSR drive circuit 102A includes solid state relay switches U2 and a second solid state relay U3, 101, each of which is preferably a type CPC1983YE (manufactured by Littelfuse/IXYS) or equivalent, rated for 600 volts and 500 milliamperes. Each SSR comprises an input light-emitting diode (LED) optically coupled to an output MOSFET switch, providing galvanic isolation between the control input and the switched output.

The output MOSFET switches of U2 and U3 are connected in series with the electromagnetic contactor CR1 coil, forming a series current path. The coil positive terminal of CR1 is connected to the first line conductor and the coil negative terminal returns through the series output switches of U2 and U3 to the second line conductor. This series connection ensures that opening either SSR output switch interrupts the coil current and causes contactor CR1 to open switches SW1 and SW2.

It will be appreciated that the series connection of two SSR output switches provides redundancy in the control path. Even if one SSR fails in a shorted condition, the other SSR can still interrupt the coil current and cause the contactor to open. Each SSR has a rated output impedance of approximately 6 ohms max on resistance for CPC1983YE. If CPC1984Y SSRs are used, that will drop to 0.6 ohms max. in the on-state and greater than 1 gigaohm in the off-state.

The input LEDs of U2 and U3 are connected in a series circuit. The LED anode of U2 is connected through a current-limiting resistor R36 to the 5V DC supply rail 105. The LED cathode of U2 is connected to the LED anode of U3. The LED cathode of U3 is connected to transistor Q1 collector.

The SSR drive circuit 102A includes Q1, Q4, and Q6 are MMBTA44 high-voltage NPN transistors arranged in a series chain in which Q1's emitter connects to Q4's collector and Q4's emitter connects to Q6's collector. The bases of Q1 and Q4 are driven from the 240V line conductor L1 through an inrush current limiting resistor R18, through the series diode network D17A and D17B, through the resistor chain R4A through R4D, with Zener diode D28A steering through diode D25 to the base of Q1 and Zener diode D28B steering through diode D26 to the base of Q4. Additionally, the base of Q6 is controlled by the power-on time delay circuit U4 (LTC1440), which holds Q6 off until the capacitor bus (C21A-D) supplying the solid state relay drive circuit 102 has charged to its full operating voltage, ensuring a clean and controlled turn-on of the contactor upon power-up. When Q1, Q4, and Q6 are all conducting, the series chain is active and energizes contactor CR1. When SCR1 fires upon detection of a ground fault or self-test event, the base drive to Q1 and Q4 is removed, the series chain turns off, the SSR relays are de-energized, contactor CR1 drops out, and SW1 and SW2 open to interrupt power to the load.

### Sense Transformer Operation

Still referring to FIG. 1, sense transformer T1 is a toroidal differential current transformer. The first line conductor L1 and the second line conductor L2 each pass through the toroidal core of T1. T1 also comprises a sense output winding (pins 1 and 2) and a self-test injection winding (pins 3 and 4), both wound on the toroidal core and magnetically coupled to the line conductors with a coupling coefficient K substantially equal to unity.

Under normal operating conditions, the current in the first line conductor and the current in the second line conductor are equal and opposite, producing equal and opposite magnetic fluxes in the toroidal core that substantially cancel. The net flux is substantially zero and the sense winding produces no output. When a ground fault occurs, the current in the first line conductor exceeds the current in the second line conductor by the amount of current flowing through the fault path to ground. This differential current produces a net flux in the core that induces a corresponding voltage in the sense winding, which is detected by IC U1 as a ground fault condition.

### Fault Detection Circuit

Still referring to FIG. 1, the ground fault detection circuit 29 comprises the following components: T1 is a toroidal differential current transformer; RCD D32A and D32B clamp the CT output during high current ground fault, to evade saturation of the CT core; C8 sets the fault integration time constant that discriminates sustained ground faults from transient noise; C7 is an AC coupling capacitor connecting the T1 sense winding output to the U1 pin 1 input network, blocking DC while passing the ground fault sense signal; R10 is a series input resistor between C7 and U1 pin 1, limiting input current and forming part of the input impedance network into the U1 pin 1 input. U1 is a FM2145 ground fault interrupter IC, although any suitable ground fault interrupter IC may be used; pin 1 (VFB) receives the AC-coupled sense signal from T1 via the D32A, D32B, C7 and R10 network; pin 3 (VREF) provides the internal 13V reference; pin 4 (GND) to circuit common; pin 5 (SCR Trigger) drives SCR1 gate directly when the internal detector threshold is exceeded, with RC and C2 forming the noise suppression network on the trigger output; pin 6 (+VS) connected to the Relay Synchronized Switch circuit 31; C13, C13A, and C13B provide temporary +VS power during self-test; pin 7 (Op Amp Output) connected back to pin 1 (VFB) through feedback resistor R3, forming the closed-loop gain network of the internal operational amplifier that sets the detection sensitivity and trip threshold; pins 2 and 8 not connected.

Sense transformer T1 senses the current differential between the two line conductors and upon a ground fault condition, e.g., leakage current from either line conductor on the load side of GFCI 11, transformer T1 induces an associated output from the sense winding. It will be appreciated that only one sense transformer is used, thus eliminating high frequency, e.g., greater than 60 Hz, nuisance tripping due to high frequency cross talk between two sense transformers used in typical GFCI circuits.

### Bi-Stable Electronic Latch Circuit

After detection of a ground fault condition on the load side of GFCI 11, U1 generates an output signal to activate latch circuit 23. Activated latch circuit 23 de-energizes the SSR circuit 102A which de-energizes contactor CR1. Latch circuit 23 includes noise suppression resistor RC on U1 pin 5 SCR Trigger output; noise suppression capacitor C2 working in conjunction with RC to prevent false triggering of SCR1 from transient noise on the trigger line; and silicon-controlled rectifier SCR1. SCR1 gate is driven directly by U1 pin 5 SCR Trigger output and latches on when U1 detects a ground fault current exceeding the trip threshold, initiating the trip sequence through the SSR drive chain.

When SCR1 fires upon detection of a ground fault SCR1 anode current diverts base drive away from Q1 and Q4, turning off the series chain. With Q1, Q4, and Q6 no longer conducting, the current flowing through the SSR input LEDs of U2 and U3 is interrupted, causing the SSR output switches to open, which de-energizes contactor coil CR1 and opens switches SW1 and SW2 to interrupt power to the load.

### Power Supply Circuit

Power supply circuit 105 provides operating power for GFCI circuit 11. The power supply derives its voltage from both line conductors L1 and L2 through two parallel half-wave rectifier paths. The L1 path comprises series rectifier diodes D16A and D16B (1N4007) and the L2 path comprises series rectifier diodes D15A and D15B (1N4007). R21A and R21B are bleed resistors to bleed off charge on dropper capacitors C11A and C11B upon powering down of capacitive dropper power supply. R9 limits the inrush current to the capacitive power supply. The voltage divider comprising R34 and R33 establishes the reference threshold for the power-on U4 sequencing circuit. C22 is a timing capacitor. When charge exceeds approximately 1.182V, the comparator outputs a high state turning on Q6, enabling turn on of SSR1 and SSR2. Series resistor R34 also feeds the SSR capacitor bus 104 comprising C21A, C21B, C21C, and C21D connected in parallel, forming the energy reservoir that supplies operating current to the solid state relay input LED drive circuit. R37 is a bleed resistor for capacitor bank C21A thru C21D to bleed off charge when unit is turned off; and, Zener diodes D30A and D30B provide voltage regulation and clamping for the lower voltage portions of the supply circuit. GFCI 11 further includes a metal-oxide varistor VR1 connected across the L1 and L2 inputs to provide line-level transient and surge protection. VR1 is preferably a type TVR20471-D (manufactured by Thinking Electronic) or equivalent, rated for a 470V working voltage.

Still referring to FIG. 1, GFCI 11 includes the SSR capacitor bus 104 pre-charge circuit (supply rail) that delays energization of SSR circuit 102A until the capacitor bus supplying the SSR input LED drive circuit 102A has charged to its full operating voltage. This prevents the SSR switches 101 from being enabled with an indeterminate gate drive voltage during power-up, which would produce uncontrolled dV/dt on the 240V load path and potential misfiring of the contactor CR1.

The pre-charge circuit comprises precision ultralow-power comparator U4 (type LTC1440 or equivalent), a voltage divider comprising resistors R34 and R33, and timing capacitor C22. R35 connects from the supply rail 104 to U4 pin 7 (V+), providing the operating supply current to the LTC1440. R35 also provides current limit for U4 in the event any of its pins are shorted. R34 connects from the supply rail to the junction of R33 and U4 pin 3 (positive comparator input), and R33 connects from that junction to L2 input, which serves as the circuit return, forming the voltage divider that sets the comparator threshold. C22 is connected between the R34/R33 junction and the L2 input, where it provides noise filtering at the positive comparator input and, together with R34 and R33, establishes the RC timing constant. The negative comparator input at U4 pin 4 connects to U4 pin 6 (REF), the LTC1440 internal precision 1.182V bandgap reference output, thereby establishing the comparator threshold against which the divided supply rail voltage at pin 3 is compared. U4 pin 5 (HYST) is also tied to U4 pin 6 (REF) to disable programmable hysteresis. U4 pin 1 (GND) and U4 pin 2 (V−) connect to L2 input, configuring the LTC1440 for single-supply operation.

The output of U4 at pin 8 drives Q6 through J1. The U4 comparator output remains low, holding the SSR drive circuit 102A off, until the bus voltage rises sufficiently that the divided voltage at U4 pin 3 exceeds the internal reference. At that threshold, U4 output at pin 8 transitions high, enabling the Q6 in the SSR input drive circuit 102A and allowing the contactor to close. This ensures that SSR circuit 102A is only activated after its drive capacitors are fully charged.

### Self-Test Circuit (Simulated Ground Fault Generator)

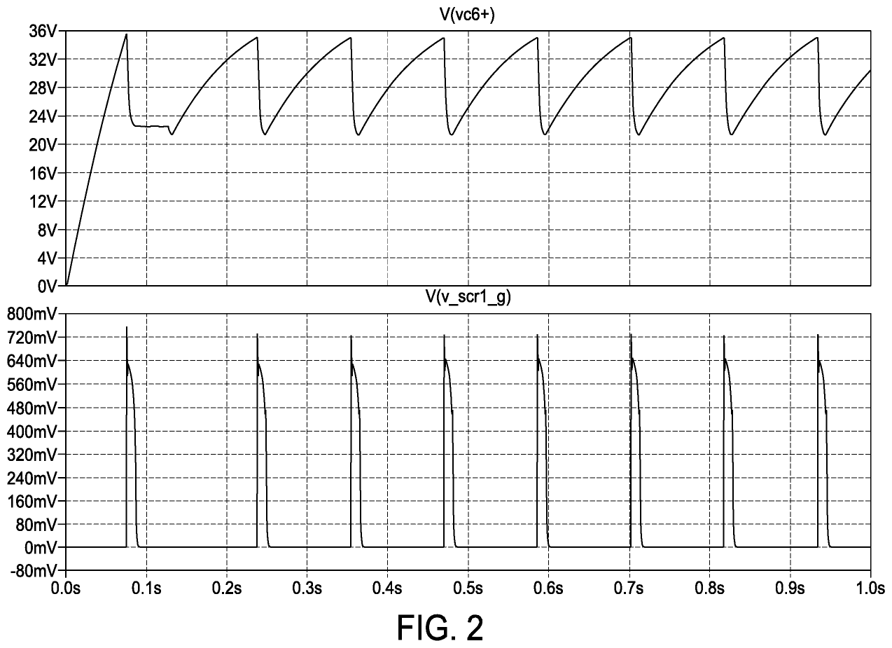

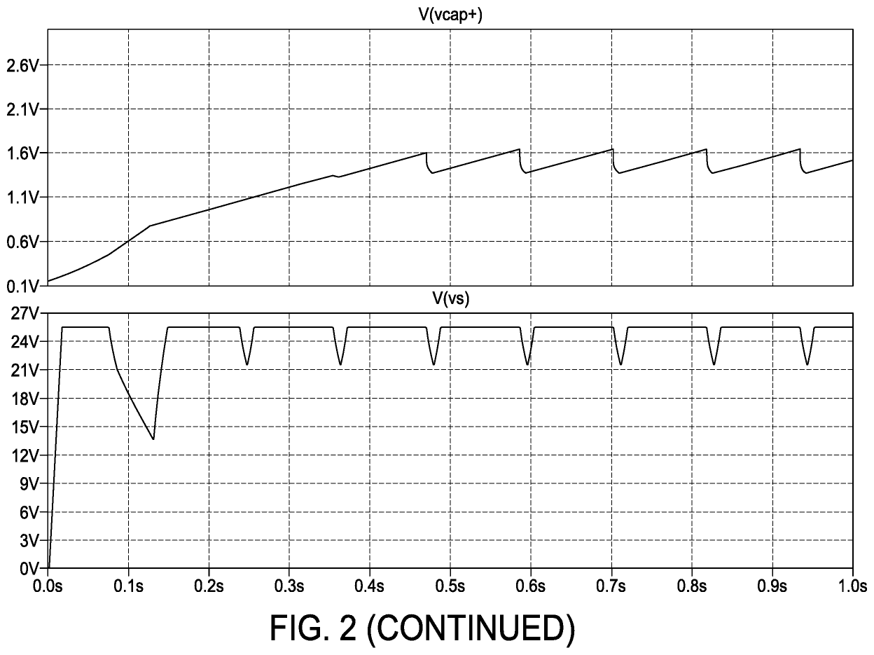

Self-test circuit 33 utilizes an internal energy storage element and a threshold device that switches to a low-impedance state at a predetermined breakover level, enabling discharge through the T1 sense transformer's self-test winding. The circuit establishes a periodic self-test signal that is transparent to the load and stable across environmental variations. Upon reaching the breakover threshold, stored energy discharges through R24 (see FIG. 2: V(vc6+) waveform) inducing a magnetically coupled signal in the T1 sense winding to simulate a ground fault; this simulated ground fault signal is processed by detection circuit 29 to generate a trigger signal (see FIG. 2: V(v_scr1_g) waveform) to activate latch circuit 23

Simultaneously, the periodic self-test signal activates the relay synchronized switch circuit 31 that isolates the SSR drive circuit 102A for the duration of the self-test window. The relay synchronized switch 31 ensures that even though SCR1 has fired the contactor coil CR1 remains energized, and SW1 and SW2 remain closed throughout the self-test event. As confirmed by the V(vs) trace of FIG. 2, the U1 supply voltage remains substantially constant during each self-test cycle. Capacitors C13, C13A, and C13B provide temporary U1 power supply to pin 6 when the GFCI 11 is in self-test mode.

Auto-monitoring end-of-life logic circuit 35 provides a discharge path through the SCR1 anode, allowing SCR1 anode current to decay below the holding current threshold so that SCR1 ceases conduction without external intervention. The holding current threshold is an inherent electrical characteristic of the selected SCR1 device that determines the duration of the self-test window—the self-test cycle is therefore self-limiting, requiring no external timing or reset signal. The stable bounded sawtooth behavior of V(vcap+) shown in FIG. 2 is the observable confirmation that SCR1 is self-commutating correctly within each self-test window—each partial discharge of the accumulated quantity reaches its lower bound and recovers to its upper bound before the next stimulus event, demonstrating that SCR1 has ceased conduction and the monitoring circuit has resumed accumulation in time for the next cycle. As long as self-test cycles are completing successfully the accumulated quantity remains within a stable bounded range well below the end-of-life threshold, as confirmed by the V(vcap+) trace of FIG. 2. It will be appreciated that the selection of SCR1 is not arbitrary—SCR1 must be chosen such that its holding current characteristic guarantees self-commutation prior to the next periodic stimulus event. Since holding current decreases with increasing temperature, the worst case condition occurs at maximum operating temperature where the self-test window is longest. SCR1 must therefore be specified with sufficient holding current at maximum operating temperature to guarantee the stable bounded V(vcap+) behavior across the full operating temperature range of −35° C. to +66° C.

It will be understood that during normal operation, i.e., not during self test, an actual ground fault triggers SCR1 on, which, through the relay synchronized switch, removes the drive voltages from the bases of Q1 and Q4.

It will be appreciated that the predetermined breakover voltage level varies with temperature. At lower temperatures the threshold decreases, resulting in shorter self-test intervals. At higher temperatures the threshold increases, resulting in longer self-test intervals. The circuit parameters are selected to ensure reliable self-test operation and SCR1 triggering across the full operating temperature range of −35° C. to +66° C.

### End-of-Life Detection and Power Denial Circuit

Still referring to FIG. 1 and FIG. 2, auto-monitoring end-of-life logic circuit 35 determines whether the self-test mechanism is functioning correctly by monitoring the cumulative response of successive self-test cycles.

During each successful self-test cycle, SCR1 conducts and the accumulated quantity of end-of-life logic circuit 35 partially discharges through SCR1 via the discharge path. (see FIG. 2: V(vcap+) waveform).

If a failure occurs anywhere in the protection chain, for example, a failed sense transformer T1, a failed fault detection IC U1, or a failed SCR, the self-test cycle will not produce a proper SCR1 conduction event. In this case the accumulated quantity in end-of-life logic circuit 35 is no longer partially discharged on each self-test cycle and accumulates without bound. When the accumulated quantity exceeds the predetermined end-of-life threshold, end-of-life logic circuit 35 activates end-of-life switch 35A, which permanently latches the GFCI in a tripped state, denying power to the load, and illuminates indicator LED 35b to alert the user that the device requires replacement.

It will be appreciated that the end-of-life detection operates without a microprocessor, using only discrete analog and passive components. The predetermined end-of-life threshold is set by a stable physical property of a passive component, providing inherent stability and reliability independent of software or programmable logic. The time window within which each self-test cycle must succeed is established by passive circuit parameters, ensuring deterministic behavior across the full operating temperature and voltage range.

### Indicator Circuit

Indicator circuit 18 provides a means of visual indication of the operational state of GFCI 11. Indicator circuit 18 includes indicator LED 1 and associated current limiting resistance. In the normal operating state, when the contactor is energized and power is being supplied to the load, the indicator LED 1 is illuminated.

### Manual Test and Reset Circuit

Test circuit 27 provides a means of manually testing GFCI circuit 11. Test circuit 27 comprises a current limiting resistor and a test switch of conventional push-in type design. When the test switch is depressed, the test circuit provides a simulated fault current through transformer T1, similar to a ground fault condition, causing the GFCI to trip and verify the complete protection chain.

GFCI 11 includes a manual reset switch 15a. Upon detection of a ground fault, SCR1 latches on and the contactor CR1 de-energizes, opening SW1 and SW2 and interrupting power to the load. The GFCI remains in this tripped state until the fault condition has been cleared and the RESET button is manually depressed. Depressing the RESET button momentarily interrupts the SCR1 anode current, reducing it below the holding current threshold of SCR1, causing SCR1 to cease conduction. With SCR1 no longer conducting, the base drive to Q1 and Q4 is restored through the relay synchronized switch circuit, the Q1/Q4/Q6 series chain resumes conduction, the SSR input LEDs are re-energized, the SSR output switches close, contactor CR1 re-energizes, and SW1 and SW2 return to the closed position restoring power to the load.

### Advantages Over Prior Art

The present invention provides several advantages over prior art GFCI devices. First, the use of an electromagnetic contactor CR1 with 60-ampere rated contacts enables reliable current interruption at power levels far exceeding those of conventional solenoid-latch GFCI mechanisms. The contactor contacts are specifically designed for high-current switching with superior arc suppression characteristics.

Second, the use of solid state relays U2, U3 in series with the contactor coil provides a clean separation between the electronic control circuitry and the high-power switching elements.

Third, the series connection of two SSR output switches provides redundancy in the control path. Even if one SSR fails in a shorted condition, the other SSR can still interrupt the coil current and cause the contactor to open.

Fourth, the use of optically-isolated SSRs provides galvanic isolation between the low-voltage control circuitry and the AC power path, enhancing safety and noise immunity.

Fifth, the self-test and end-of-life circuits are implemented entirely with discrete analog components, eliminating the cost, complexity, and potential software failure modes associated with microprocessor-based designs.

The versions of the present invention described above are intended to be merely exemplary and those skilled in the art shall be able to make many variations and changes to it without departing from the spirit of the present invention. All such variations and changes are intended to be within the scope of the present invention as defined in the appended claims. For example, the particular parts which make up the embodiments may be interchanged or combined to form more embodiments. The contactor may be any suitable electromagnetic contactor rated for the intended application. The solid state relays may be any suitable optically-isolated SSR. The GFCI IC may be any suitable ground fault detection integrated circuit. The voltage and current ratings may be adapted for different applications.

What is claimed is:

1. A ground fault circuit interrupter (GFCI) for interrupting the flow of current through a pair of lines, wherein one of the pair of lines extends between a first line input and a first line output and the other line extends between a second line input and a second line output, the GFCI comprising:
an electromagnetic contactor rated for at least 60 amperes at 240 volts alternating current and having a coil and a first normally-open switch connected between the first line input and the first line output and a second normally-open switch connected between the second line input and the second line output;
at least one solid state relay (SSR) having an optically-isolated input and a switched output, the switched output connected in series with the electromagnetic contactor coil such that de-energizing the SSR input causes the switched output to open and de-energize the contactor coil, thereby opening the first and second switches; and
a fault detection circuit comprising a single sense transformer configured to detect a ground fault current imbalance between the first and second line conductors and to de-energize the electromagnetic contactor in response thereto.

2. The GFCI as in claim 1 wherein the at least one SSR comprises a first SSR and a second SSR, and wherein the switched outputs of the first SSR and the second SSR are connected in series with the electromagnetic contactor coil.

3. The GFCI as in claim 1 wherein the fault detection circuit further comprises a bi-stable electronic latch circuit comprising a silicon-controlled rectifier (SCR) operable in either a conductive or a non-conductive state, the SCR being configured to de-energize the electromagnetic contactor upon detection of a ground fault.

4. The GFCI as in claim 3 wherein the fault detection circuit further comprises a ground fault detection integrated circuit coupled to the sense transformer and configured to trigger the SCR upon detection of a current imbalance exceeding a predetermined ground fault threshold.

5. The GFCI as in claim 1 further comprising a simulated ground fault generator, an auto-monitoring logic module, and an end-of-life switch for permanently disabling the electromagnetic contactor if the GFCI fails the self-test.

6. The GFCI as in claim 5 wherein the simulated ground fault generator comprises a periodic stimulus circuit configured to charge an energy storage element from a supply voltage and to discharge the energy storage element through a self-test winding magnetically coupled to the sense transformer upon the energy storage element reaching a predetermined breakover threshold, thereby periodically inducing a simulated ground fault signal in the sense transformer.

7. The GFCI as in claim 5 wherein the auto-monitoring logic module comprises:
a monitoring circuit that continuously accumulates an electrical quantity; and
a threshold detector that generates an end-of-life signal when the accumulated quantity exceeds a predetermined threshold,
wherein each successful self-test cycle partially discharges the accumulated quantity maintaining it within a stable bounded range below the predetermined threshold, and wherein failure of the protection chain prevents the discharge causing the accumulated quantity to rise continuously until the predetermined threshold is reached.

8. The GFCI as in claim 7 wherein the auto-monitoring logic module comprises a discharge circuit connected to the anode of a silicon-controlled rectifier, wherein the duration of each self-test discharge event is determined by the holding current characteristic of the silicon-controlled rectifier, the self-test cycle terminating inherently when the discharge current falls below the holding current threshold.

9. The GFCI as in claim 8 wherein the silicon-controlled rectifier has a holding current characteristic sufficient to guarantee cessation of conduction prior to the next periodic stimulus event of the simulated ground fault generator at maximum operating temperature, whereby the auto-monitoring logic module maintains stable bounded behavior across the full operating temperature range.

10. The GFCI as in claim 1 wherein the at least one SSR is a MOSFET-output solid state relay.

11. The GFCI as in claim 1 further comprising a transient voltage suppressor network connected across the at least one SSR.

12. A ground fault circuit interrupter system for protecting a 240-volt, 60-ampere AC circuit, the system comprising:
a toroidal sense transformer through which a first line conductor and a second line conductor pass, the sense transformer further comprising a sense winding and a self-test winding wound on the toroidal core, all magnetically coupled, and wherein the system does not comprise a second sense transformer;
a ground fault detection integrated circuit connected to the sense winding, configured to detect current imbalances indicative of a ground fault;
a silicon-controlled rectifier (SCR) having its gate connected to an output of the ground fault detection integrated circuit;
a pair of optically-isolated solid state relays, each having an LED input and a MOSFET output, the LED inputs connected in series in a circuit controlled by the SCR;
a 240-volt, 60-ampere rated electromagnetic contactor having a coil connected in series with the MOSFET outputs of the pair of solid state relays, and having a first normally-open contact on the first line conductor and a second normally-open contact on the second line conductor;
a relay synchronized switch circuit configured to maintain energization of the electromagnetic contactor coil and the pair of solid state relays during each self-test event;
a self-test circuit comprising a periodic stimulus generator and the self-test winding, configured to periodically inject a simulated ground fault signal into the sense transformer at intervals determined by circuit parameters; and
an end-of-life circuit configured to accumulate a monitored quantity responsive to self-test cycle activity, to compare the monitored quantity against a predetermined end-of-life threshold, and to permanently deny power to the load when the monitored quantity exceeds the end-of-life threshold.

13. The system of claim 12, wherein the self-test circuit and the end-of-life circuit comprise discrete analog and passive components.

14. A ground fault circuit interrupter (GFCI) for interrupting the flow of current through a pair of lines, wherein one of the pair of lines extends between a first line input and a first line output and the other line extends between a second line input and a second line output, the GFCI comprising:
A 240-volt, 60-ampere rated electromagnetic contactor having a coil and a first normally-open switch connected between the first line input and the first line output and a second normally-open switch connected between the second line input and the second line output;
at least one solid state relay (SSR) having an optically-isolated input and a switched output, the switched output connected in series with the electromagnetic contactor coil such that de-energizing the SSR input causes the switched output to open and de-energize the contactor coil;
a capacitor bus configured to supply operating current to the SSR input, the capacitor bus being charged from a power supply connected across the first and second line inputs;
a power-on delay circuit configured to inhibit energization of the SSR input until the capacitor bus voltage has risen to a predetermined operating threshold, thereby ensuring controlled turn-on of the electromagnetic contactor upon application of line voltage; and
a fault detection circuit configured to de-energize the SSR input upon detection of a ground fault current imbalance between the lines.

15. The GFCI as in claim 14 wherein the power-on delay circuit comprises a comparator having a first input connected to a voltage divider across the capacitor bus, a second input connected to an internal reference voltage, and an output configured to enable the SSR input when the voltage divider output exceeds the internal reference voltage.

16. The GFCI as in claim 15 wherein the comparator is a precision comparator and the internal reference voltage is a bandgap reference voltage.

17. The GFCI as in claim 14 further comprising a relay synchronized switch circuit activated simultaneously with a simulated ground fault stimulus event and configured to maintain energization of the electromagnetic contactor coil and the at least one SSR for the duration of the self-test window, such that the electromagnetic contactor remains closed and load power is uninterrupted during each self-test cycle.

18. The GFCI as in claim 17 wherein the relay synchronized switch circuit is activated by the same stimulus event that generates the simulated ground fault signal, such that activation of the relay synchronized switch circuit and injection of the simulated ground fault signal are inherently synchronous.
